(19) United States
(12) Patent Application Publication
(10) Pub. No.: US 2026/0023900 A1
(43) Pub. Date: Jan. 22, 2026

(54) TECHNIQUES FOR OPTIMAL PESTICIDE APPLICATION BASED ON FIELD-SPECIFIC WEATHER FORECASTING

(71) Applicant: Drift-Sense, Ltd., Jerusalem (IL)

(72) Inventors: Elad SEGAL, Rosh HaAyin (IL); Ran SHAULI, Jerusalem (IL); Pavel KUNIN, Yavne (IL)

(73) Assignee: Drift-Sense, Ltd., Jerusalem (IL)

(21) Appl. No.: 19/345,972

(22) Filed: Sep. 30, 2025

Related U.S. Application Data
(63) Continuation of application No. PCT/IB2024/053159, filed on Apr. 1, 2024.
(60) Provisional application No. 63/494,045, filed on Apr. 4, 2023.

(51) Int. Cl. G06F 30/27

(52) U.S. Cl. CPC G06F 30/27

(57) ABSTRACT

Techniques for determining an optimal application approach to a crop field are provided. The method includes generating a field-specific dataset that is customized for a respective crop field, wherein the field-specific dataset includes weather forecast data and regulatory data; determining, using a trained spray efficiency (SE) model, an initial spray SE score, wherein the initial SE score is determined by applying the field-specific dataset and physicochemical data to the trained SE model; determining a final SE score by combining the initial SE score and at least one uncertainty score; and generating an application recommendation for the respective crop field based on the determined final SE score.

### CROSS-REFERENCE TO RELATED APPLICATIONS

This application is a continuation of International Application No. PCT/IB2024/053159, filed on Apr. 1, 2024, now pending, which claims the benefit of U.S. Provisional Application No. 63/494,045 filed on Apr. 4, 2023. The contents of the above-referenced applications are hereby incorporated by reference.

### TECHNICAL FIELD

The present disclosure generally relates to agricultural applications and more particularly to performing optimal pesticide application using a machine learning algorithm.

### BACKGROUND

Pesticides are widely used in agricultural, forestation, and recreational settings to protect growing plants from pests such as, but not limited to, weeds, fungi, insects, and more. These pesticides, which may be any one of herbicide, insecticide, nematicide, ovicide, larvicide, molluscicide, animal repellent, insect repellent, fungicide, and more, are delivered to fields of growing plants to ensure improved food safety, quality, and sustainability. Accurate application of pesticides can protect growing plants from being damaged through unwanted consumption, destruction of property, spread of diseases, and more.

Currently implemented methods of pesticide delivery (or application) include, for example, but not limited to, seed treatment, spray application, and crop dusting. Seed treatment applies the pesticides to the seed before planting and is effective against soil-borne risks. Spray application delivers pesticides, often, in liquid form through a mechanical sprayer. Crop dusting involves spraying of crops using dry powder forms of pesticides, from, for example, a ground vehicle, an aircraft, and the like.

Despite the benefits of protecting the field of growing plants from pests, pesticides, being mostly chemicals, may be potentially harmful to the natural and human environments, humans, other species, as well as the growing plant themselves without accurate control in delivery. Some damaging factors from pesticide application may include poisoned land or water, development of pest resistance, loss of sprayed materials, and more. Particularly, the most commonly used spray application of pesticides is associated with spray drift, an unintentional drift of pesticide that results in pesticides being applied, for example, outside the target area, within the target area but unable to reach the target growing plant, into soil or nearby water sources by leaching, to surroundings (e.g., adjacent land, workers, residences, passersby, etc.) through airborne exposure, and more. To this end, minimizing environmental and health hazards without comprising pesticide effectiveness against pests remains a challenge.

One of the factors that influence spray drifts in pesticide application is the weather conditions, for example, temperature, humidity, wind, and the like, of an area. Thus, accurate weather forecasts and utilization of such forecasts can be advantageous in supporting faster and smarter decisions in agricultural applications.

However, it has been identified that current methods of weather forecasting are determined for a larger geographical region, which may be inconsistent with weather conditions for a particular target area such as a field of growing plants. Moreover, such weather forecasting is often analyzed as isolated data that discount other relevant elements of the field, for example, landscape, soil, growing plants, and the like, and more, that influence spray drifts in pesticide applications.

It would therefore be advantageous to provide a solution that would overcome the challenges noted above.

### SUMMARY

A summary of several example embodiments of the disclosure follows. This summary is provided for the convenience of the reader to provide a basic understanding of such embodiments and does not wholly define the breadth of the disclosure. This summary is not an extensive overview of all contemplated embodiments, and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “some embodiments” or “certain embodiments” may be used herein to refer to a single embodiment or multiple embodiments of the disclosure.

Certain embodiments disclosed herein include a method for determining an optimal application approach to a crop field. The method comprises: generating a field-specific dataset that is customized for a respective crop field, wherein the field-specific dataset includes weather forecast data and regulatory data; determining, using a trained spray efficiency (SE) model, an initial spray SE score, wherein the initial SE score is determined by applying the field-specific dataset and physicochemical data to the trained SE model; determining a final SE score by combining the initial SE score and at least one uncertainty score; and generating an application recommendation for the respective crop field based on the determined final SE score.

Certain embodiments disclosed herein also include a non-transitory computer readable medium having stored thereon causing a processing circuitry to execute a process, the process comprising: generating a field-specific dataset that is customized for a respective crop field, wherein the field-specific dataset includes weather forecast data and regulatory data; determining, using a trained spray efficiency (SE) model, an initial spray SE score, wherein the initial SE score is determined by applying the field-specific dataset and physicochemical data to the trained SE model; determining a final SE score by combining the initial SE score and at least one uncertainty score; and generating an application recommendation for the respective crop field based on the determined final SE score.

Certain embodiments disclosed herein also include a system for determining an optimal application approach to a crop field. The system comprises: a processing circuitry; and a memory, the memory containing instructions that, when executed by the processing circuitry, configure the system to: generate a field-specific dataset that is customized for a respective crop field, wherein the field-specific dataset includes weather forecast data and regulatory data; determine, using a trained spray efficiency (SE) model, an initial spray SE score, wherein the initial SE score is determined by applying the field-specific dataset and physicochemical data to the trained SE model; determine a final SE score by combining the initial SE score and at least one uncertainty score; and generate an application recommendation for the respective crop field based on the determined final SE score.

Certain embodiments disclosed herein include the method, non-transitory computer readable medium, or system noted above, further including or being configured to perform the following steps: identifying a subset of the field-specific dataset by applying a plurality of filtering rules, wherein the plurality of filtering rules defines predetermined threshold values, wherein the subset of field-specific data includes field-specific data that are within a range bound by the predetermined threshold values.

Certain embodiments disclosed herein include the method, non-transitory computer readable medium, or system noted above, further including or being configured to perform the following steps: causing display of the application recommendation for an application event via a user device, wherein the application recommendation describes at least one of: a schedule, a day, a time, and a duration for the application event of the crop field.

Certain embodiments disclosed herein include the method, non-transitory computer readable medium, or system noted above, wherein the field-specific dataset is generated from input data that includes at least one of: meteorological data of the crop respective field, regulation of a region, and user data of the respective field.

Certain embodiments disclosed herein include the method, non-transitory computer readable medium, or system noted above, further including or being configured to perform the following steps: determining the meteorological data by applying a trained weather forecast (WRF) model to raw meteorological data, wherein the raw meteorological data is received from an external forecast system for the region, wherein the WRF model generates additional weather parameters from the raw meteorological data.

Certain embodiments disclosed herein include the method, non-transitory computer readable medium, or system noted above, further including or being configured to perform the following steps: estimating the at least one uncertainty score from the field-specific dataset, wherein the at least one uncertainty score indicates a potential error in the field-specific dataset.

Certain embodiments disclosed herein include the method, non-transitory computer readable medium, or system noted above, wherein the potential error of the at least one uncertainty score is at least one of: a breach of regulations from weather shifts, a weather forecasting error, and a location determination error.

Certain embodiments disclosed herein include the method, non-transitory computer readable medium, or system noted above, wherein the application recommendation is generated for a plurality of time windows at a predetermined time interval.

Certain embodiments disclosed herein include the method, non-transitory computer readable medium, or system noted above, further including or being configured to perform the following steps: receiving a droplet movement data including droplet sizes and concentrations, wherein the droplet movement data is determined through simulation of a dispersion model; initially training the SE model for a plurality of weather conditions using the received droplet movement data; and updating the SE model based on feedback data from the generated application recommendation.

Certain embodiments disclosed herein include the method, non-transitory computer readable medium, or system noted above, wherein the training of the trained SE model is performed using at least one of: an extreme Gradient Boosting (XGBoost), decision treen, linear regression, Lasso regression, Ridge regression, neural network, and deep neural network.

### BRIEF DESCRIPTION OF THE DRAWINGS

The subject matter disclosed herein is particularly pointed out and distinctly claimed in the claims at the conclusion of the specification. The foregoing and other objects, features, and advantages of the disclosed embodiments will be apparent from the following detailed description taken in conjunction with the accompanying drawings.

FIG. 1 is a network diagram utilized to describe the various embodiments.

FIG. 2 is a flowchart illustrating a method for generating spray recommendations for optimal pesticide application according to an embodiment.

FIG. 3 is a flowchart illustrating a method for training a spray efficiency model according to an embodiment.

FIG. 4 is a schematic diagram of a system according to an embodiment.

### DETAILED DESCRIPTION

It is important to note that the embodiments disclosed herein are only examples of the many advantageous uses of the innovative teachings herein. In general, statements made in the specification of the present application do not necessarily limit any of the various claimed embodiments. Moreover, some statements may apply to some inventive features but not to others. In general, unless otherwise indicated, singular elements may be in plural and vice versa with no loss of generality. In the drawings, like numerals refer to like parts through several views.

The various disclosed embodiments provide a system and method for generating optimized spray recommendations (or application recommendations) for a target area. A weather forecasting model is trained and utilized to accurately determine weather conditions for a particular area of interest (e.g., field, groups of fields, and the like). The accurate predictions of weather conditions are utilized by applying a spray efficiency model to determine spray efficiency scores for each time window over a period of time. It should be noted that the spray efficiencies are determined in consideration of field specifications such as, but not limited to, location, crop type, application equipment, and the like, and more, as well as regulations that match such field specifications. It should be further noted that optimized spray recommendations may be determined for various environments such as, but not limited to, agricultural settings, foresting environments, recreational environments (e.g., parks, turfs, etc.), and more.

The disclosed embodiments generate field-specific datasets that are specifically and selectively created for the particular target area. It should be noted the field-specific datasets include applicable datasets excluding unrelated data to reduce processing power and speed necessary to determine spray efficiencies and recommendations. Moreover, the disclosed embodiments, using field-specific datasets, provide improved accuracy in predicting spray efficiency by accounting for potential spray drifts in order to recommend pesticide applications at conditions with high pesticide effectivity and low environmental damage.

The disclosed embodiments further provide methods of objective decision making for pesticide application. In addition to the inaccuracies in currently available weather forecasts, decisions on pesticide application are often subjectively made on how it “feels” or “looks” right to apply pesticide to a field. However, the disclosed embodiments generate spray efficiency scores for each potential time window based on data processing by at least one algorithm. According to the disclosed embodiments, such scores are utilized to objectively determine optimal spray application conditions and time windows with improved consistency and accuracy.

Moreover, the disclosed embodiments utilize a plurality of filtering rules to identify a subset of field-specific data. It should be noted that the plurality of filtering rules based on weather forecast data and regulatory data enables objective rule-based determination of possible conditions for pesticide application and furthermore, conserves memory and processing power by reducing the amount of data for processing. To this end, the various disclosed embodiments herein enable effective data processing in order to determine optimal pesticide application conditions and optical application approaches for the specific field with improved accuracy and specificity while conserving computational resources.

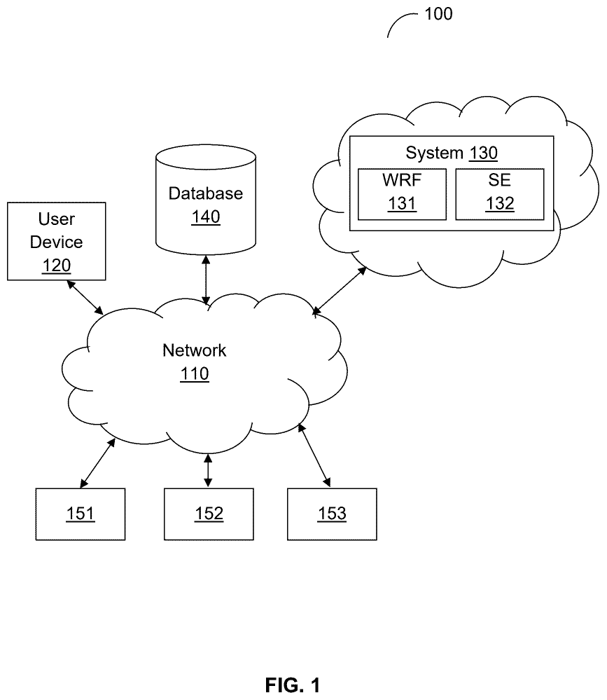

FIG. 1 shows an example network diagram 100 utilized to describe the various disclosed embodiments. In the example network diagram 100, a user device 120, a system 130, a database 140, a meteorology source 151, a regulation source 152, and a physicochemical data source 153 are communicatively connected via a network 110. The network 110 may be, but is not limited to, a wireless, cellular, or wired network, a local area network (LAN), a wide area network (WAN), a metro area network (MAN), the Internet, the world wide web (WWW), similar networks, and any combination thereof.

The user device 120 may be, but is not limited to, a personal computer, a laptop, a tablet computer, a smartphone, a wearable computing device, or any other device capable of receiving, processing, and displaying notifications. The user device 120 may be configured to display notifications associated with, for example, but not limited to, weather forecast, spray efficiencies, spray recommendations, and the like, of a target area (e.g., a specific field, group of fields, area including the specific field, or the like, and more), as generated by the system 130. In an embodiment, the user device 120 is utilized by a user (e.g., a grower) to input user data defining preferences for pesticide applications, such as, and without limitation, field data, application equipment, time windows, frequencies, pesticide type, and the like, and any combination thereof.

The user data received through the user device 120 is transmitted and used as input data in the system 130, in order to generate field-specific datasets for pesticide application. In an embodiment, the field-specific dataset is utilized to determine spray efficiencies and recommendations, as well as notifications, in accordance with the user data. In a further embodiment, a field profile including the user data may be generated and stored at a database 140. In an embodiment, the field profile indicates attributes of the field such as, but not limited to, size, landscape, surrounding and/or adjacent land, type of crop, target crop grade, and the like, which may be collected from user input data via a user device 120 and/or external sources. It should be noted that one user device 120 is shown for illustrative purposes, however, more than one user device may be connected to communicate over the network 110. In some example embodiments, the user device to input user data and the user device to display the notification (e.g., recommendation) may be different and individually connected to the system 130 via the network 110.

The external sources, the meteorology source 151, the regulation source 152, and the physicochemical data source 153 are each configured to provide data to the system 130 over the network 110. The meteorology source 151 provides raw meteorological data of a larger geographical region and the regulation source 152 provides regulation data on pesticide application in the region in which the target area is located, for example, country, state, county, and the like. In an embodiment, such raw meteorological data and regulation data may be processed together with the user data to generate field-specific datasets. The regulation source 152 may also provide regulation data for other agrochemical applications including, for example, materials used for prevention of diseases, growth control, pest treatment, seeding, fertilizing, and the like, and any combination thereof. In addition, physicochemical properties of certain pesticides may be provided by the physicochemical data source 153 for application in the field. Physiochemical properties may include, for example, but are not limited to, compatible temperatures, radiation properties, toxicity, and the like, and more, of relevant pesticides.

The system 130 is configured to generate field-specific datasets for pesticide application at the target area based on input data, for example, but not limited to, user data, regulations of region, meteorological data, and the like. The field-specific dataset defines properties that are specific for the field and/or target area accounting for the various input data. In an embodiment, the field-specific dataset is determined considering the input data received from the user device 120 and other external sources such as, but not limited to, a meteorology source 151, a regulation source 152, a physicochemical data source 153, and the like. In a further embodiment, the weather forecast data is determined based on output of a weather forecasting (WRF) model 131 that generates meteorological data for the specific target area given the raw data from external sources as described herein.

The field-specific dataset includes values for data such as, but not limited to, regulatory data, weather forecast data, and the like, and any combination thereof. In an example embodiment, the data of the field-specific dataset are determined based on particular field information, for example, field location, crop type, equipment, meteorological data, location, and the like, and any combination thereof. The regulatory data includes constraints on times and conditions for pesticide application not only from the regulations of the larger geographical region but also based on the field profile (e.g., landscape, adjacent land, bodies of water, crop type, and the like, and more). The weather forecast data defines weather predictions for each time window (e.g., 1 hour time window) that is specific to the target area and the given pesticide application. In an embodiment, the field-specific dataset generated for the target area may be intermittently updated based on changes in various input data. In an embodiment, the field-specific dataset may be stored in the database 140. In a further embodiment, portions of the field-specific dataset may be combined to be stored in the database 140. In an embodiment, the user data may be stored together with the field-specific dataset.

According to the disclosed embodiments, the system 130 stores a weather forecasting (WRF) model 131 that is configured to determine meteorological data of a target area by applying at least one algorithm to raw meteorological data of a larger location collected from the meteorology source 151. The target area is a smaller geographical area within a larger geographical area in which the raw meteorological data was collected for. That is, the WRF model 131 determines meteorological data that are higher in resolution than that of conventional weather forecast sources in order to provide meteorological data of the particular, smaller target area. The meteorology source 151 is an external entity such as, without limitation, a Global Forecast System. In an embodiment, the WRF model 131 runs in the background to continuously, intermittently, or regularly, determine meteorological data for the specific target area. In a further embodiment, the determined meteorological data for the target area is utilized, for example at few hour intervals, to determine weather forecast data of the field-specific dataset.

In an embodiment, the meteorological data of the target area includes weather parameters such as, but not limited to, temperature, humidity, wind speed and direction, turbulence, near-ground inversion, and more, at time intervals. In an example embodiment, the time interval may be 1 hour for the meteorological data to include weather parameter values for every hour. It should be noted that data for additional weather parameters (e.g., turbulence, near-ground inversion, etc.) are determined by the WRF model 131 to increase accuracy in predicting weather conditions and recommending pesticide application. In an example embodiment, the meteorological data for the target area may include data for a 7-day period and may be updated by applying the WRF model 131 every 12 hours to reflect changes in, for example, atmospheric conditions. In some embodiments, the weather forecast dataset may be updated intermittently through data assimilation of new raw meteorological data collected from the meteorology source 151.

According to disclosed embodiments, the WRF model 131 adapts a nested domain configuration to determine high resolution meteorological data for the target area. The WRF model 131 is configured to define an inner and an outer domain, where the inner domain is within the larger outer domain and is a zoomed-in area with boundaries closer to the target area. The outer and inner domains include a plurality of grid points that covers the area within the domain. In an embodiment, the target area including the specific field of interest may be described by at least one grid point of the plurality of grid points covering the inner domain. As an example, depending on the size of the target area, the target area may include one grid point, many grid points, or all grid points of the inner domain.

According to the disclosed embodiments, the system 130 further includes a spray efficiency (SE) model 132 that is configured to apply at least one algorithm to generate spray efficiencies as described herein. The SE model 132 can have a learning mode and a prediction mode, where the learning mode may include training of the model by applying an algorithm, such as a supervised machine learning algorithm and a semi-supervised machine learning algorithm, using the training dataset. The algorithm used for training may include, for example, an extreme Gradient Boosting (XGBoost), decision treen, linear regression, Lasso regression, Ridge regression, neural network, deep neural network, and the like.

In an embodiment, the SE model 132 is trained using field-specific datasets and physicochemical property data generated from various input data. Further optimization of the SE model 132 is performed based on feedback data received from the user (e.g., farmer, grower, etc.) after the occurrence of a spraying event. In some embodiments, the SE model 132 is initially trained from the droplet movement data obtained from simulation of a dispersion model and additional training by applying an algorithm, such as a reinforcement machine learning algorithm, to the feedback data.

At least one algorithm, such as a machine learning algorithm, is applied to, for example, but not limited to, field-specific datasets, physicochemical property data of pesticides, historical field data, and the like, for the determination of the spray efficiencies. The spray efficiencies are presented as scores that indicate high efficiency, highly effective pesticide application with low damage to the environment, with a large score. In an embodiment, spray efficiencies (i.e., the scores) are determined for every applicable time window at certain time intervals, for example, every hour. The applicable time windows are narrowed through the process outlined herein and identified as part of the spray efficiency output. For example, spray efficiencies are determined for time windows that are not prohibited based on, for example, but not limited to, regulations in the region, regulations from the landscape, user preference, forbidden wind speed, direction, and the like.

The historical field data may include previous spray efficiency scores and/or performed spray events as well as feedback data collected from previous recommendations and/or spraying events. In some embodiments, the historical field data may include analyzed data of the spray event and feedback data collected. The historical field data may be stored at and retrieved from the database 140. The database 140 may be part of the system 130 or may be separate and communicatively connected via the network 110.

The SE model 132 takes in field-specific datasets and physicochemical data, which account for additional weather parameters, field, and user specified data including regulatory data. It should be noted that processing of such data at the SE model 132 allows the determination of spray efficiency of the particular target area with improved accuracy. It should be further noted that the SE model 132 is provided only with relevant data to reduce processing time and speed in determining the spray efficiencies.

According to the disclosed embodiments, the system 130 is further configured to generate spray recommendations based on the determination of spray efficiencies for the target area. The spray recommendations provide, for example, but not limited to, day, time, duration, and the like, and any combination thereof, that allows effective application of pesticides to the field in the upcoming hours and/or days. As noted above, it should be noted that the spray recommendation is optimized for the specific field, equipment, pesticide, and more.

In an embodiment, the spray recommendations are generated by a final score that combines the spray efficiency score and uncertainty scores for each time window. The uncertainty scores estimate potential errors in, for example, but not limited to, weather shifts, weather forecasts, location, and the like. The uncertainty score of weather shifts (e_{shift}) estimates a probability that the weather condition would change in breach of regulations identified in the regulatory data of the field-specific dataset. In addition, the uncertainty scores of the weather forecast (e_{forecast}) and the location (e_{location}) estimates a probability of errors in determining meteorological data (or weather forecast data) for the target area and the location of the target area from the larger geographical area, respectively. In an embodiment, the uncertainty scores are determined by applying at least one algorithm to the field-specific datasets including, for example, regulatory data, weather forecast data, and the like, and any combination thereof.

As an example, a high uncertainty score (e_{shift}) is determined for a time window that is not predicted to rain (i.e., expect high application effectivity), but has a 40% chance of rain and a high probability of wind direction change to the north, towards residential areas. The high uncertainty score here reflects regulations that restrict pesticide application in the field when the wind direction is towards the residential area. In another example, the same weather predictions, of a 40% chance of rain and high probability of wind direction change to the north, are made in a second field that is located far away from regulated surroundings (e.g., residential area, bodies of water, and the like). A low uncertainty score may be determined for the second field since the change of wind direction does not violate regulatory data for the particular field. In an example embodiment, the uncertainty scores are any real numbers between 0.1 and 10.

In a further embodiment, the spray recommendations are classified by ranges of scores. As an example, time windows with scores within upper and lower threshold values may be determined suitable for spraying. In some embodiments, the spray recommendation is a spray schedule for the field. In an embodiment, the final score indicates the efficacy of the pesticide while lowering environmental risks. In an example embodiment, a high spray efficiency score predicts that pesticide spraying at this time and condition will be effective for target pests and less damaging to other environmental factors, for example, the growing plant, soil, adjacent fields, and the like. It should be noted that the spray efficiency (SE) model 132 enables objective decision-making for pesticide application considering the various elements of the target area (i.e., field-specific). It should be further noted that the spray recommendations generated herein predict and avoid potential spray drifts that may occur during pesticide application for improvements in the application as well as safety of many environmental factors.

According to some embodiments, portions of the field-specific dataset such as, but not limited to, regulatory data, weather forecast data, and the like, and any combination thereof, are filtered prior to applying the algorithm of the SE model 132 based on a plurality of filtering rules. The plurality of filtering rules may be defined by at least one of the regulatory data and the weather forecast data. Filtering out eliminates portions of the weather forecast data, weather conditions, and/or time windows, that are incompliant to at least one of the plurality of filtering rules and thus, unfavorable for pesticide application.

In an embodiment, threshold values are determined with respect to each of, for example, the regulatory data and the weather forecast data, and are utilized in the plurality of filtering rules. It should be noted that the plurality of filtering rules enables objective decision making in determining a subset of weather forecast data. To this end, in an embodiment, the subset of weather forecast data, excluding non-compliant weather conditions based on regulatory and weather forecast data, is used as input data at the SE model 132. The subset of weather forecast data includes weather conditions, parameters, and the like, of potential spray time windows for the specific field in view of the regulatory data and weather forecast data. In a further embodiment, the subset of the weather forecast data is processed and transformed to apply the SE model 132 and/or an uncertainty algorithm. In a further embodiment, a subset of field-specific dataset may be generated based on the subset of weather forecast data.

As an example, the field-specific dataset includes weather forecast data for every hour for the next 24 hours as well as regulatory data for a field. Based on the filtering rules of the regulatory data and the weather forecast data, hours from 1 am to 4 am are eliminated regardless of the weather forecast data (e.g., humidity, temperature, etc.). In addition, based on the regulatory data, hours indicating high wind speed and/or temperature below pesticide functional temperature are eliminated. To this end, only a subset of weather forecast data is identified as potential spray times (or conditions) and utilized for further analysis to determine spray efficiency scores and/or recommendations.

It should be noted that the regulation source 152 and the physicochemical data source 153 are external sources that provide the most up-to-date information for these features to the system 130. The regulations indicate spray application regulations of the region, for example, country, county, or the like. In an embodiment, the system 130 is configured to receive up-to-date information and further configured to extract and process the information in order to generate regulatory data and physicochemical data for the target area. In an example embodiment, regulatory data may include, without limitation, time windows, buffer zones, landscape, atmospheric conditions, chemical components, equipment, and the like, and more. In an embodiment, the extracted and processed regulatory data and physicochemical data are stored at a database 140. In a further embodiment, the database 140 may be part of the system 130 or may be separate and communicatively connected via the network 110.

It should be noted that updates and changes in such physicochemical data and regulations may be readily implemented in the system 130 for accurate analyses in accordance with current regulations, properties, and user data. For example, regulations for a pesticide may change to enhance protection of the environment and people in the vicinity. In such an example scenario, the system 130 is configured to apply the more stringent regulations in all associated processes in determining spray recommendations. It should be further noted that implementation of such updated information can be applied immediately without delay and/or user involvement.

It should be noted that the disclosed embodiments are described with respect to a field with crops for illustrative purposes and do not limit the scope of the various disclosed embodiments described herein. The various disclosed embodiments may be utilized in forests, recreational areas (e.g., parks, turfs, etc.), and the like where pesticides may be applied. It should be further noted that the present disclosure is described with respect to the application of pesticides for illustrative purposes and does not limit the scope of the present disclosure. An ordinary skill in the part would understand that the disclosed embodiments may be utilized for other chemicals, or the like, that are applied in, for example, but not limited to, crop fields, forests, recreational areas, and the like, and any combination thereof.

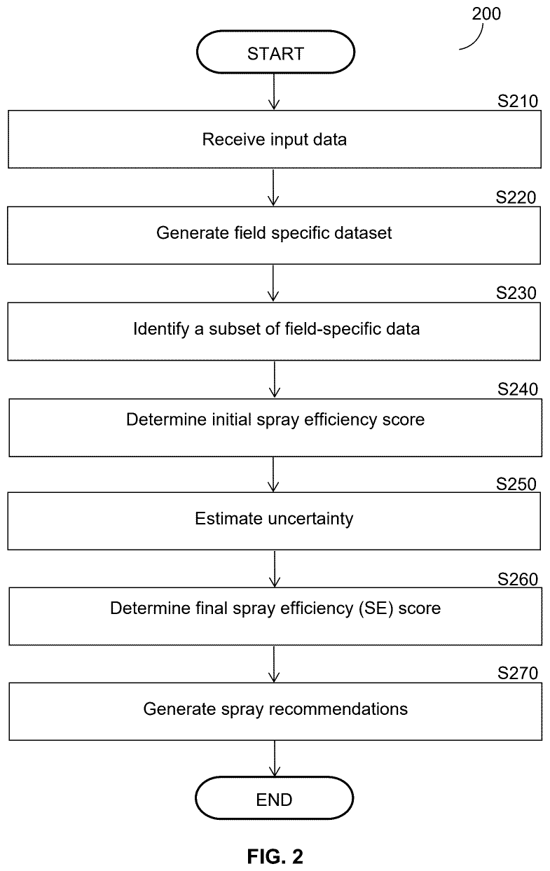

FIG. 2 is an example flowchart 200 illustrating a method for generating spray recommendations for optimal pesticide application on a target area according to an embodiment. The method described herein is performed by the system 130, FIG. 1. In an embodiment, the target area is an area of land including a field of interest. In an embodiment, the process of generating spray recommendations may be repeatedly performed as new or updated meteorological data is received intermittently or regularly. It should be noted that the updates from external sources such as, for example, but not limited to, changes to regulations, new equipment will be utilized, and more may be readily implemented in the method to generate accurate spray recommendations for the current criteria.

At S210, input data is received. The input data include, for example, but not limited to, user data, regulations of the region, raw meteorological data, and the like. Such input data is received from a user and/or other external sources. In some embodiments, the input data such as regulations of the region may be stored in a database (e.g., the database 140, FIG. 1) and/or a memory. External sources may include meteorology sources and regulation sources (e.g., the meteorology source 151 and regulation sources 152, FIG. 1) that provide the most up-to-date information intermittently or regularly. The input data is collected in association with the target area that includes the specific field of interest. It should be noted that the regulations and the raw meteorological data of the input data are common for fields within a larger region and may not be specific to the field and/or target area of interest. In an embodiment, the input data may be directly received from the corresponding component and/or from the database (e.g., the database 140, FIG. 1) over the network (e.g., the network 110, FIG. 1).

The raw meteorological data collected from the meteorology source include data for a larger geographical region including the target area. For example, raw meteorological data from the external meteorology source is for an area corresponding to a city or groups of cities in close vicinity. The raw meteorological data may include data for upcoming days or weeks for the larger geographical region. In an embodiment, such raw meteorological data is applied to a trained weather forecasting (WRF) model (e.g., the WRF model 131, FIG. 1) to determine meteorological data for a smaller geographical target area and/or field. In an embodiment, the determined meteorological data includes data for the target area (i.e., a smaller region including the specific field within the larger geographical region) at, for example, and without limitation, 1 hour intervals. The meteorological data include values for weather parameters such as, but not limited to, temperature, humidity, wind speed and direction, turbulence, inversion, and more. It should be noted that the determined meteorological data includes additional weather parameters not readily available and retrieved from the external meteorology source. In an embodiment, the meteorological data for the smaller target area that are output from the WRF model are utilized for further processing below.

In an embodiment, the determination of meteorological data for the smaller target area by the WRF model is performed continuously utilizing intermittently collected new raw meteorological data for the larger geographical region, for example, from the external meteorology source. In an embodiment, the meteorological data is updated upon receiving new data from the meteorology source. As an example, new data for 7 days at 1 hour intervals are collected for a larger geographical region every 12 hours. Upon receiving new data, at every 12 hours, meteorological data are determined and updated for the target area. In an embodiment, the WRF model may continuously run in the background to update meteorological data over time. In an example embodiment, receiving meteorological data as input may be performed at predefined time intervals and/or frequencies apart from the WRF model outputting updated meteorological data.

The user data is collected for the field from a user (e.g., grower, farmer, manager, and the like) of the field and may be received via a user device (e.g., the user device 120, FIG. 1). In some embodiments, the user data may be already collected and stored in a memory and/or database for retrieval. The user data includes field-related data such as, but not limited to, field location, crop type, application equipment, pesticide type, and the like, as well as preferences in spray time windows, frequencies, and the like. In an embodiment, a field profile including the user data may be created for each field and/or target area.

At S220, field-specific datasets are generated. The field-specific datasets define characteristics of the particular field and/or target area based on the received input. That is, the field-specific dataset includes regulatory data, weather forecast data, and the like that are distinctly customized for the target area. In an embodiment, forbidden winds are determined for the target area as part of the regulatory data. The forbidden wind is a constraint for pesticide application to the specific field to protect sensitive areas in the field and/or the surrounding environment of the field. In an embodiment, the forbidden wind defines threshold values for wind parameters such as, but not limited to, direction, speed, and the like.

As an example, the field-specific datasets may differ between two fields just adjacent to each other based on the input data (e.g., determined meteorological data and user data of each field), even though the raw meteorological data and the regulations for the larger region are similar. As another example, two different field-specific datasets may be generated for the same field based on the user data such as crop type, pesticide type, and the equipment to be used. In the same example, the regulatory data that match backpack spray equipment may be completely different from regulatory data that match boom sprayers attached to tractors.

In an embodiment, the field-specific dataset includes weather forecast data determined for the target area based on received input data of raw meteorological data, regulations of the region, and the user data. The weather forecast data is extracted and identified from the meteorological data of the target area with respect to user data for the field. As discussed above, in an embodiment, the meteorological data for the target area is an output from the WRF model (e.g., the WRF model 131, FIG. 1). To this end, the weather forecast data may be updated intermittently or regularly according to the updates from the WRF model. In some embodiment, the field-specific dataset includes combined data of the weather forecast data and the regulatory data. In an embodiment, the generated field-specific data may be stored in a memory and/or a database (e.g., the database 140, FIG. 1).

At S230, a subset of field-specific data is identified by applying at least one of a plurality of filtering rules. In an embodiment, the plurality of filtering rules is defined by the regulatory data and the weather forecast data for the particular field in order to output a score for each rule. The identified subset includes portions of the generated field-specific data indicating potential pesticide application conditions. In an example embodiment, the subset of field-specific data includes time windows for potential spraying of pesticides including regulatory data and weather forecast data (e.g., wind speed and direction, humidity, turbulence, and the like, and more) associated with each time window.

In an embodiment, the plurality of filtering rules includes threshold values to eliminate unsuitable weather conditions for pesticide application. In a further embodiment, the threshold values are determined for each of, for example, the regulatory data, the weather forecast data, and the like, and utilized as one of the plurality of filtering rules. It should be noted that the plurality of rules of determined threshold values enables objectively identifying the subset of field-specific data that indicate potential pesticide application time windows and further conserves unnecessary processing power. In a further embodiment, the subset of weather forecast data is further processed and transformed.

As an example, the subset of field-specific data may include weather forecast data of time windows for which the regulation score is greater than the determined threshold value, and thus, pesticide application is permitted according to the regulatory data of the field. In another example embodiment, the subset includes weather forecast data of time windows when the weather score is greater than the determined threshold value and includes weather conditions that are low in humidity, rain probability, and wind speed. In an example embodiment, a binary scoring approach is applied to the field-specific dataset with respect to each of the plurality of filtering rules. For example, time windows that display a bad weather condition and a violation of regulatory rules are given scores of 1 and 0, respectively. In a further example embodiment, such scores are utilized to eliminate unfavorable, or restricted, time windows for the next steps of processing.

At S240, initial spray efficiency scores are determined for the subset of field-specific dataset. A trained spray efficiency (SE) model (e.g., the SE model 132, FIG. 1) is applied to the subset of field-specific datasets of, for example, but not limited to, weather forecast data, to determine initial spray efficiency scores for each applicable time window for pesticide application. The weather forecast data includes values for various weather parameters such as, but not limited to, temperature, humidity, wind speed and direction, turbulence, and the like, and any combination thereof.

In addition to the field-specific datasets, physicochemical property data, historical field data, and user data (e.g., application equipment) are applied to the SE model. The physicochemical property data indicates properties of the pesticide used in the field and is determined based on user data and external data received from the physicochemical source (e.g., the physicochemical data source 153, FIG. 1). The historical field data includes, for example, but not limited to, field-specific datasets, physicochemical data, and feedback data of past spray events that were recommended to a user (e.g., a farmer, a grower, a site manager, and the like). In an example embodiment, the historical field data are for the particular field for which the field-specific datasets are generated for. In another example embodiment, the historical field data includes field-specific datasets, physiochemical data, and feedback data for any spray efficiency scores determined using the SE model regardless of field, pesticide, equipment, or the like.

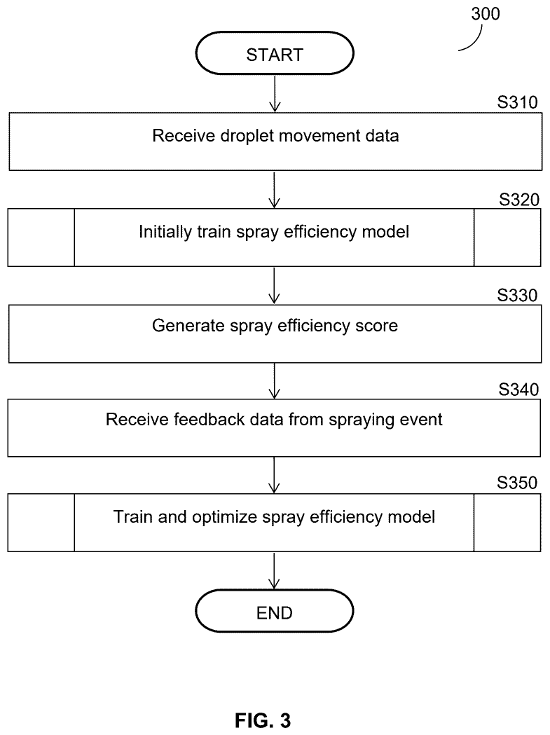

In an embodiment, spray efficiency scores are generated for each time window of the weather forecast data to indicate the effectiveness of pesticide spraying while minimizing harm to other environmental factors for the respective time window. The environmental factors include, for example, but are not limited to, the farmer, growing crops, soil, water sources, adjacent fields, passersby, and the like, and more. In an example embodiment, a high spray efficiency score of a time window suggests highly effective pesticide application while lowering the risk of damage to the field itself and any other surrounding environments. In another example embodiment, a low spray efficiency score of a time window suggests ineffective and potentially detrimental results upon spraying the pesticides on the field. The SE model applies at least one of a supervised machine learning and a semi-supervised machine learning algorithm and training of the SE model is described further in FIG. 3.

At S250, uncertainty scores are estimated from the subset of field-specific datasets. At least one algorithm may be applied to the subset of field-specific datasets to gauge risks and/or errors associated with the determined weather conditions. The risks associated with the uncertainty scores are potentially damaging effects to the environment that violate regulations as defined in, for example, the regulatory data. In an embodiment, the uncertainty scores are determined for each time window of the plurality of time windows in the subset of field-specific datasets. In a further embodiment, the uncertainty scores may be determined with respect to different aspects such as, but not limited to, forecast errors, chances of weather condition shifts, locational error, and the like.

In an example embodiment, the forecast error (e_{forecast}) indicates a reliability of meteorological data by comparing one or more preceding meteorological data and the locational error (e_{location}) points to an error in location determination by comparing weather forecast data of surrounding or adjacent locations. As an example, a high forecast error (e_{forecast}) is determined for a time window when values of weather parameters display large divergences between 2 previously received meteorological data. In another example, locational error (e_{location}) is determined by utilizing weather forecast data of the 3 closest grid points to the grid point of the target area. In an example embodiment, the weather shift error (e_{shift}) describes the possibility of changes in the weather within a certain time window. As an example, a high uncertainty score indicates a high probability that the potential change in weather condition may be harmful or in breach of regulations. As another example, a low uncertainty score may indicate a low chance of weather condition change and/or a low chance that the change in weather condition will go against regulations defined in the regulatory data.

At S260, the final spray efficiency (SE) score is determined. In an embodiment, the final SE score is determined by combining the determined initial spray efficiency score (S240) and the uncertainty scores (S250) for each time window. It should be noted that the final SE score predicts the efficiency of pesticide application at this time window in account of potential changes and errors that may increase environmental damage.

In an example embodiment, the final spray efficiency (SE) score is determined according to the equation as shown below:

$$Final SE Score = {s}_{0} - {e}_{forecast} - {e}_{shift} - {e}_{location} \qquad ( 1 )$$

The example equation 1 above calculates a final spray efficiency score by subtracting potential errors from the forecast, e_{forecast}, based on previous weather forecast datasets, weather shifts, e_{shift}, and location, e_{location}, based on close grid points from the initial efficiency score, so, that is output by the spray efficiency model. It should be noted that the calculation of errors described herein are examples for illustrative purposes and does not limit the scope of the disclosed embodiments.

At S270, spray recommendations are generated for the target area. The spray recommendation is generated based on the determined final SE scores. In an embodiment, the plurality of time windows in the subset of field-specific datasets is classified into groups based on the respective final spray efficiency score. That is, time windows in the same group have respective final spray efficiency scores in the same range of scores. In an embodiment, each of the time windows may be labeled according to the classification. In an embodiment, the classified spray recommendations may be caused to be displayed on a user device (e.g., the user device 120, FIG. 1). The user may select and execute the pesticide application as recommended. In an embodiment, user feedback data may be collected for the spray event that takes place based on the generated spray recommendation. In a further embodiment, the display of generated spray recommendations and interactions with the user may be performed through a graphical user interface (GUI) via the user device. In some embodiments, the spray recommendation may include a schedule of recommended spraying events for upcoming days.

It should be noted that the method described to generate a spray recommendation for optimal spraying conditions is used for illustrative purposes and does not limit the scope of the disclosed embodiments. The method described herein may be applied to other pesticide application methods for example, but not limited to, seed application, crop dusting, and the like, and more.

FIG. 3 is an example flowchart 300 illustrating a method for training a spray efficiency (SE) model according to an embodiment. The method described herein is performed by the system 130, FIG. 1. At least one algorithm, such as a supervised machine learning algorithm, a semi-supervised machine learning algorithm, and a reinforcement machine learning algorithm, is applied to the training data. The machine algorithm used for training may include, for example, an extreme Gradient Boosting (XGBoost), decision treen, linear regression, Lasso regression, Ridge regression, neural network, deep neural network, and the like.

At S310, droplet movement data is received. The droplet movement provides atmospheric information in association with the weather. In an embodiment, the droplet data is determined through the simulation of a dispersion model. The droplet movement data includes, for example, but is not limited to, droplet sizes, concentrations, and the like. and more.

At S320, SE model is initially trained with the droplet movement data. The SE model is first trained using the droplet movement data to determine spray efficiencies at different atmospheric conditions. In an embodiment, the initial training of the SE model is based on weather conditions and parameters associated with different conditions.

At S330, initial spray efficiency scores are generated based on the initially trained SE model. The field-specific datasets including, for example, regulatory data, weather forecast data, and the like, are applied to the SE model to generate initial spray efficiency scores for each of the time windows available in the field-specific datasets. Spray recommendations are generated and caused to be provided to a user as described herein above.

At S340, feedback data from executed spray events are received. In an embodiment, the feedback data is received from a user (e.g., a farmer, field manager, and the like) via a user device (e.g., the user device 120, FIG. 1). In an embodiment, the feedback data is collected for the spray events that were performed based on the presented spray recommendations. In an example embodiment, feedback data may be collected on the spray recommendation without actual performance of the spray event. In an embodiment, the feedback data is associated with the spray recommendation data and stored in a memory and/or database (e.g., the database 140, FIG. 1). In a further embodiment, the feedback data and associated spray recommendation data may be stored as historical field data in a memory and/or database.

At S350, SE model is further trained and optimized based on received feedback data. The SE model is further optimized by accounting for additional data such as, but not limited to, regulatory data, weather forecast data, physicochemical data, feedback data, and the like, in addition to the initial training using the droplet movement data. In an embodiment, the training and optimization of the SE model is continuously and intermittently performed as feedback data is received. It should be noted that further training of the SE model improves accuracy in generating spray efficiency scores that are customized for various field features (e.g., field profile, location, etc.).

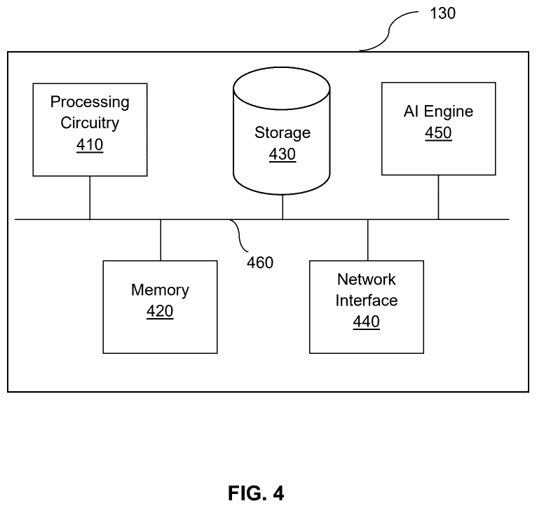

FIG. 4 is an example schematic diagram of a system 130 according to an embodiment. The system 130 includes a processing circuitry 410 coupled to a memory 420, a storage 430, a network interface 440, and an artificial intelligence (AI) engine 450. In an embodiment, the components of the system 130 may be communicatively connected via a bus 460.

The processing circuitry 410 may be realized as one or more hardware logic components and circuits. For example, and without limitation, illustrative types of hardware logic components that can be used include field programmable gate arrays (FPGAs), application-specific integrated circuits (ASICs), Application-specific standard products (ASSPs), system-on-a-chip systems (SOCs), graphics processing units (GPUs), tensor processing units (TPUs), general-purpose microprocessors, microcontrollers, digital signal processors (DSPs), and the like, or any other hardware logic components that can perform calculations or other manipulations of information.

The memory 420 may be volatile (e.g., random access memory, etc.), non-volatile (e.g., read only memory, flash memory, etc.), or a combination thereof.

In one configuration, software for implementing one or more embodiments disclosed herein may be stored in the storage 430. In another configuration, the memory 420 is configured to store such software. Software shall be construed broadly to mean any type of instructions, whether referred to as software, firmware, middleware, microcode, hardware description language, or otherwise. Instructions may include code (e.g., in source code format, binary code format, executable code format, or any other suitable format of code). The instructions, when executed by the processing circuitry 410, cause the processing circuitry 410 to perform the various processes described herein.

The storage 430 may be magnetic storage, optical storage, and the like, and may be realized, for example, as flash memory or other memory technology, compact disk-read only memory (CD-ROM), Digital Versatile Disks (DVDs), or any other medium which can be used to store the desired information.

The network interface 440 allows the system 130 to communicate with, for example, the network 110.

The AI engine 450 may be realized as one or more hardware logic components and circuits, including graphics processing units (GPUs), tensor processing units (TPUs), neural processing units, vision processing units (VPU), reconfigurable field-programmable gate arrays (FPGA), and the like. The AI engine 450 is configured to perform, for example, machine learning based on input data such as a field-specific dataset, physicochemical property data, historical field data, user data, and more, received over the network 110.

It should be understood that the embodiments described herein are not limited to the specific architecture illustrated in FIG. 4, and other architectures may be equally used without departing from the scope of the disclosed embodiments.

The various embodiments disclosed herein can be implemented as hardware, firmware, software, or any combination thereof. Moreover, the software is preferably implemented as an application program tangibly embodied on a program storage unit or computer readable medium consisting of parts, or of certain devices and/or a combination of devices. The application program may be uploaded to, and executed by, a machine comprising any suitable architecture. Preferably, the machine is implemented on a computer platform having hardware such as one or more central processing units (“CPUs”), a memory, and input/output interfaces. The computer platform may also include an operating system and microinstruction code. The various processes and functions described herein may be either part of the microinstruction code or part of the application program, or any combination thereof, which may be executed by a CPU, whether or not such a computer or processor is explicitly shown. In addition, various other peripheral units may be connected to the computer platform such as an additional data storage unit and a printing unit. Furthermore, a non-transitory computer readable medium is any computer readable medium except for a transitory propagating signal.

All examples and conditional language recited herein are intended for pedagogical purposes to aid the reader in understanding the principles of the disclosed embodiment and the concepts contributed by the inventor to furthering the art and are to be construed as being without limitation to such specifically recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

It should be understood that any reference to an element herein using a designation such as “first,” “second,” and so forth does not generally limit the quantity or order of those elements. Rather, these designations are generally used herein as a convenient method of distinguishing between two or more elements or instances of an element. Thus, a reference to first and second elements does not mean that only two elements may be employed there or that the first element must precede the second element in some manner. Also, unless stated otherwise, a set of elements comprises one or more elements.

As used herein, the phrase “at least one of” followed by a listing of items means that any of the listed items can be utilized individually, or any combination of two or more of the listed items can be utilized. For example, if a system is described as including “at least one of A, B, and C,” the system can include A alone; B alone; C alone; 2A; 2B; 2C; 3A; A and B in combination; B and C in combination; A and C in combination; A, B, and C in combination; 2A and C in combination; A, 3B, and 2C in combination; and the like.

What is claimed is:

1. A method for determining an optimal application approach to a crop field, comprising:
generating a field-specific dataset that is customized for a respective crop field, wherein the field-specific dataset includes weather forecast data and regulatory data;
determining, using a trained spray efficiency (SE) model, an initial spray SE score, wherein the initial SE score is determined by applying the field-specific dataset and physicochemical data to the trained SE model;
determining a final SE score by combining the initial SE score and at least one uncertainty score; and
generating an application recommendation for the respective crop field based on the determined final SE score.

2. The method of claim 1, further comprising:
identifying a subset of the field-specific dataset by applying a plurality of filtering rules, wherein the plurality of filtering rules defines predetermined threshold values, wherein the subset of field-specific data includes field-specific data that are within a range bound by the predetermined threshold values.

3. The method of claim 1, further comprising:
causing display of the application recommendation for an application event via a user device, wherein the application recommendation describes at least one of: a schedule, a day, a time, and a duration for the application event of the crop field.

4. The method of claim 1, wherein the field-specific dataset is generated from input data that includes at least one of: meteorological data of the crop respective field, regulation of a region, and user data of the respective field.

5. The method of claim 4, further comprising:
determining the meteorological data by applying a trained weather forecast (WRF) model to raw meteorological data, wherein the raw meteorological data is received from an external forecast system for the region, wherein the WRF model generates additional weather parameters from the raw meteorological data.

6. The method of claim 1, further comprising:
estimating the at least one uncertainty score from the field-specific dataset, wherein the at least one uncertainty score indicates a potential error in the field-specific dataset.

7. The method of claim 6, wherein the potential error of the at least one uncertainty score is at least one of: a breach of regulations from weather shifts, a weather forecasting error, and a location determination error.

8. The method of claim 1, wherein the application recommendation is generated for a plurality of time windows at a predetermined time interval.

9. The method of claim 1, wherein training of the trained SE model further comprises:
receiving a droplet movement data including droplet sizes and concentrations, wherein the droplet movement data is determined through simulation of a dispersion model;
initially training the SE model for a plurality of weather conditions using the received droplet movement data; and
updating the SE model based on feedback data from the generated application recommendation.

10. The method of claim 9, wherein the training of the trained SE model is performed using at least one of: an extreme Gradient Boosting (XGBoost), decision treen, linear regression, Lasso regression, Ridge regression, neural network, and deep neural network.

11. A non-transitory computer readable medium having stored thereon instructions for causing a processing circuitry to execute a process, the process comprising:
generating a field-specific dataset that is customized for a respective crop field, wherein the field-specific dataset includes weather forecast data and regulatory data;
determining, using a trained spray efficiency (SE) model, an initial spray SE score, wherein the initial SE score is determined by applying the field-specific dataset and physicochemical data to the trained SE model;
determining a final SE score by combining the initial SE score and at least one uncertainty score; and
generating an application recommendation for the respective crop field based on the determined final SE score.

12. A system for determining an optimal application approach to a crop field, comprising:
a processing circuitry; and
a memory, the memory containing instructions that, when executed by the processing circuitry, configure the system to:
generate a field-specific dataset that is customized for a respective crop field, wherein the field-specific dataset includes weather forecast data and regulatory data;
determine, using a trained spray efficiency (SE) model, an initial spray SE score, wherein the initial SE score is determined by applying the field-specific dataset and physicochemical data to the trained SE model;
determine a final SE score by combining the initial SE score and at least one uncertainty score; and
generate an application recommendation for the respective crop field based on the determined final SE score.

13. The system of claim 12, wherein the system is further configured to:
identify a subset of the field-specific dataset by applying a plurality of filtering rules, wherein the plurality of filtering rules defines predetermined threshold values, wherein the subset of field-specific data includes field-specific data that are within a range bound by the predetermined threshold values.

14. The system of claim 12, wherein the system is further configured to:
cause display of the application recommendation for an application event via a user device, wherein the application recommendation describes at least one of: a schedule, a day, a time, and a duration for the application event of the crop field.

15. The system of claim 12, wherein the field-specific dataset is generated from input data that includes at least one of: meteorological data of the crop respective field, regulation of a region, and user data of the respective field.

16. The system of claim 15, wherein the system is further configured to:
determine the meteorological data by applying a trained weather forecast (WRF) model to raw meteorological data, wherein the raw meteorological data is received from an external forecast system for the region, wherein the WRF model generates additional weather parameters from the raw meteorological data.

17. The system of claim 12, wherein the system is further configured to:
estimate the at least one uncertainty score from the field-specific dataset, wherein the at least one uncertainty score indicates a potential error in the field-specific dataset.

18. The system of claim 17, wherein the potential error of the at least one uncertainty score is at least one of: a breach of regulations from weather shifts, a weather forecasting error, and a location determination error.

19. The system of claim 12, wherein the application recommendation is generated for a plurality of time windows at a predetermined time interval.

20. The system of claim 12, wherein the system is further configured to:
receive a droplet movement data including droplet sizes and concentrations, wherein the droplet movement data is determined through simulation of a dispersion model;
initially train the SE model for a plurality of weather conditions using the received droplet movement data; and
update the SE model based on feedback data from the generated application recommendation.

21. The system of claim 20, wherein training of the trained SE model is performed using at least one of: an extreme Gradient Boosting (XGBoost), decision treen, linear regression, Lasso regression, Ridge regression, neural network, and deep neural network.
